(19) United States
(12) Patent Application Publication
(10) Pub. No.: US 2010/0040773 A1
(43) Pub. Date: Feb. 18, 2010

(54) Method and Composition to Repair Pinholes and Microvoids in Immersion Silver Plated PWB's Thereby Relieving Creep Corrosion

(76) Inventor: John J. Grunwald, Ramat-Gan (IL)

Correspondence Address: ARTHUR G. SCHAIER;CARMODY & TORRANCE LLP, 50 LEAVENWORTH STREET, P.O. BOX 1110, WATERBURY, CT, 06721, US

(21) Appl. No.: 12/579,547

(22) Filed: Oct. 15, 2009

(30) Foreign Application Priority Data
Sep. 7, 2009 (IL) 200772

(51) Int. Cl. B05D 1/00

(52) U.S. Cl. 427/142

(57) ABSTRACT

This patent discloses embodiments that overcome the deficiencies of pinholes and porosities that plague immersion deposited metal coatings deposited as a final finish to throughole copper Printed Wiring Boards(PWB'S). The patent focuses particularly on silver immersion plated PWB's, where pinholes in the silver film lead to creep corrosion, resulting in failure of costly PWB assemblies in the field. Said pinholes and microvoids are repaired by capping them with electrolessly plated metal, preferably silver.

### BACKGROUND OF THE INVENTION

Solderability of through hole copper plated PWBs, and their long term corrosion resistance, are the two indispensable performance requirements of the electronics industry.

In the past, the above requirements have been eminently fulfilled by the well known hot air leveling (HAL) process. Indeed, for many decades HAL was an industry standard. Due however to environmental and perhaps more importantly, planarity considerations, HAL is no longer an attractive choice.

Replacement processes for PAL can be summarized as follows:
1. Electroless nickel plate followed by electroless or immersion gold.
2. Immersion deposited tin.
3.Immersion deposited silver.

None of above processes can quite match the outstanding performance of HAL. Indeed, HAL envelopes the copper - patterned panel hermetically, with no copper exposed to the environment. It thus offers unequaled solderability and corrosion resistance. However, as mentioned earlier, it is no longer widely practiced due to its environmental and planarity shortcomings. Thus, the industry must find accommodation with one of above finishes.

Immersion coatings of metals over copper are inherently pinholed and porous, leaving exposed copper spots that are the major causes for performance failure in the field of costly interconnect assemblies.

In the case of immersion coatings used to preserve solderability of PC boards, one typically deals with displacement reactions of metals such as tin and silver over copper. In recent developments, immersion silver is gaining preference over immersion tin for achieving both corrosion protection and long term solderability of printed wiring boards. While immersion silver is making inroads for solderability of interconnect assemblies, electroless nickel followed by immersion or electroless gold, still remains a widely practiced industry choice, wherever its high cost is affordable/justifiable. Indeed, they are perceived to offer reasonably durable protection over long periods of time, without the need of being topped with polymer coatings in order to be shielded from corrosive environments.

Again, the main shortcoming of the cost-attractive immersion, or displacement-coated metals such as immersion tin or silver, is their inherent porosity. Indeed, the driving force for the displacement reaction of silver or tin over copper, is the release of electrons by the dissolving copper metal, which electrons then act as reducing agents that convert silver ions into metallic silver or stannous tin into tin metal. The deposition mechanism is one of a galvanic cell, wherein the dissolving copper metal acts as the anode with respect to the silver or tin.

It follows, that copper metal must unavoidably always be exposed, for silver metal deposition to take place. It also follows, that there can never be 100% coverage of galvanically deposited silver metal over the copper substrate, resulting in pinholes and microvoids. The same holds true for tin immersion coatings over copper, or for that matter, for any galvanically deposited displacement type metal.

The unavoidable pinholes of exposed copper metal continue to generate galvanic attack, as the PWB assembly is exposed to a corrosive environment due to high humidity and/or air pollution. Such exposures lead to progressive creep corrosion, wherein copper corrosion products migrate to the surface of the printed circuit, ultimately leading to failure of costly interconnect assemblies with LSI components attached thereon.

This invention offers embodiments that overcome the deficiencies of pinholed, porous immersion silver deposits covering copper-patterned PWB's, by capping them with electrolessly plated metal.

### PRIOR ART

The prior art, in its attempt to combat corrosion of silver immersion coatings, principally focuses on organic polymer films applied over the immersion silver, as a means to “plug” the pores or pinholes of exposed copper.

Recently published application WO 200975162 A1 by Abys and assigned to Enthone, is referenced herewith in its entirety. It exemplifies attempts to prevent corrosion and especially creep corrosion, of immersion silver-plated copper. To that end, Abys recommends contacting the silver-plated copper with compositions of organic thiols that protect the silver, and amines that protect copper.

WO 2009064329 by Long and assigned to MacDermid, discloses polymer compositions for combating silver corrosion, that may further comprise ethoxylated polyalcohols and metal-bearing compounds such as molybdates, tungstates, and the like.

The problem with polymer compounds covering immersion deposits such as silver, resides in the fact that they may not hermetically cover or seal the pinholes that expose the copper substrate, and therefore cannot completely avoid exposure of the silver immersion layer to corrosive environments. Furthermore, many of the polymer films tend to swell and become fractured or cracked over time, resulting in relatively short-lived corrosion protection. It can thus be understood, that protection offered by polymer films against tarnish and/or corrosion does not live up to industry expectations for durable performance in corrosive environments.

Reference TW 408189 discloses a silver immersion composition that possibly exemplifies typical silver immersion formulations used in the industry. It also corroborates the deposition mechanism, as being driven by anodic dissolution of copper.

### DESCRIPTION OF THE INVENTION

It is the object of this invention to achieve silver films without plate discontinuities and microvoids. In one embodiment of this patent, pinhole-free silver films are achieved, by opting for chemical reducer-based electroless silver, as opposed to displacement type immersion silver.

The prior art abounds with electroless silver compositions and processes such as for example, U.S. Pat. No. 5,322,553 by Mandich and assigned to Applied Electroless Concepts. The above referenced patent features an electroless silver composition that is purported to be stable over long periods of time, is autocatalytic and can build heavy thicknesses, comparable to those obtainable with electroless nickel or copper.

The chemistry of Mandich's patent comprises a monovalent silver complex, a dual reducer combination of thiosulfate and sulfite, with optional additives such as EDTA. Its operating pH is mildly alkaline, and recommended plating temperatures are in the range of 50° C. Silver plating is processed over electroless nickel and not directly over copper. In spite of the stated appealing features of above referenced electroless silver process, it is not believed to be widely practiced in the field. The likely reason possibly resides in its marginal bath stability, resulting in a narrow operating window. One is thus prompted to conclude that U.S. Pat. No. 5,322,553 is not user-friendly and cannot be readily implemented to achieve autocatalytic silver plating, and at the same time be free of extraneous, uncontrollable reduction of silver that leads to massive plate-out on walls of the container, followed by decomposition of the solution.

It can also be concluded that based on information to date, none of the prior art's autocatalytic electroless silver compositions and methods have achieved significant acceptance as a finish for copper patterned PWB's. Again, it is reasonable to assume that the main cause is the inability of the prior art to design silver compositions that offer both autocatalytic plating of silver metal and freedom from extraneous and undesirable silver deposition on the solder mask, that eventually leads to bulk decomposition of the plating solution. Also, it can be hypothesized that silver metal is not truly autocatalytic if the plating bath is formulated using reducers that ensure bath stability.

Thus, electroless silver seems to behave unlike other reducer-based electroless processes, such as formaldehyde-based copper formulations or hypophosphite-bearing electroless nickel electrolytes. Indeed, the latter can autocatalytically deposit thicknesses of 25 microns or more, and at the same time plating baths are stable over very long periods of time.

In yet another embodiment of this invention, electroless silver is deposited over immersion deposited silver, since it provides silver films thicker and more robust than is achievable with immersion silver alone, and most importantly, will eliminate bare copper spots due to intrinsic microvoids in immersion deposits.

This patent also envisions plating electroless silver on top of electroless nickel, cobalt, or alloys thereof In such embodiment, the electroless nickel, cobalt, or their alloys, will maximize corrosion protection, whereas the electroless silver provides solderability. Such embodiment can conveniently replace current processes based on electroless nickel followed by immersion gold.

It is a further object of this invention to enable electroless silver deposition directly over copper, overcoming the deficiencies of the prior art, namely uncontrolled extraneous plate.

This patent hypothesizes, without being bound by theory, that any minimal thickness of reducer-based electroless metal, especially silver, deposited on top of the porous immersion silver film, will be a significant improvement over the immersion silver alone as-deposited, or even when the latter is capped by organic compounds in general, and polymers in particular.

When formulating a stable electroless, reducer-based silver composition that will not function in displacement mode, one will need to first expose the copper surface to an activator, or catalyst solution, before electroless silver can take place. Such activators can be chosen from the prior art and are usually based on aqueous compounds of palladium, gold, etc.

In formulating a catalyst or activator solution, and selecting optimum process conditions that will enable electroless silver deposition over the copper substrate, one will avoid excessive or insufficient activation. The former will result in extraneous metallization of the solder mask, while the latter may fail to initiate the electroless deposition process. For example, the well known and widely practiced colloidal tin/palladium catalyst compositions would seem unattractive, as they will wet the solder mask, leading to undesirable silver deposition thereon.

This patent however, does envision applying tin/palladium colloidal compositions over copper as a possible final finish for solderability, potentially replacing tin immersion. A preferred embodiment of this patent obviates extraneous silver deposition on solder mask by capitalizing on the hydrophobic nature of the solder mask surface. Indeed, aqueous activators will wet the metal surface and adhere to it, but will be repelled by the surface of the solder mask.

In a further embodiment, this patent seeks to formulate an electroless, reducer-based silver composition that will first form a silver film over copper in the displacement mode, then the reducer will additionally deposit the desired thickness of silver metal over the immersion deposited fragile and porous immersion silver.

Alternatively, the patent proposes the use of stabilized electroless silver compositions, that will necessitate exposing the copper patterned PVB to activating solutions, such as aqueous palladium chloride, for initiating reducer-based electroless silver plating. Such highly stable electroless compositions will insure selectivity, with silver plating taking place solely on the copper, and not on the solder mask.

Once again, and at the risk of being redundant, this patent improves upon the prior art's shortcomings, wherein presence of pinholes and microvoids are intrinsic to galvanic deposition, and unavoidably result in dissimilar metals, i.e. silver and copper being exposed to the atmosphere, which act as galvanic corrosion sites.

This patent theorizes that in order to stop or at least substantially minimize galvanic corrosion of silver immersion plates over a copper substrate, one needs to cap the pinholes with metal, and preferably a metal that will not promote galvanic corrosion of the copper substrate.

Indeed, as mentioned earlier, organic molecules or polymer films applied over silver, only offer short term relief in somewhat delaying the onset of thermodynamically driven galvanic corrosion. In order to arrest or at least significantly reduce long term corrosion, one needs to eliminate the galvanic cell created by exposure of dissimilar metals (i.e. copper and silver) to humid and/or corrosive environments.

### DETAILED DESCRIPTION OF THE INVENTION

The principal object of this invention is to prevent formation, or repair pinholes and microvoids present in silver deposits over copper substrates. The former can be achieved by using reducer-based electroless silver as opposed to displacement type processes, whereas the latter is embodied by capping said pinholes and microvoids in the immersion silver deposited layer with metal, as opposed to organic films of the prior art.

In this invention, elimination of pinholes signifies a very substantial reduction of said pinholes, as compared to massive pinholes and porosities present in galvanically deposited silver layers. Indeed, it is well known to those skilled in the art, that electrolessly deposited metals such as electroless copper and electroless nickel, may at times encounter some microvoids, due for example to entrapped gas bubbles, soiled surface spots, etc.

Once again, a preferred embodiment of this invention envisions topping the pores inherently present in immersion or displacement silver deposits over copper with metal, and preferably a metal that will offer no electrochemical driving force for galvanic corrosion.

In yet another preferred embodiment of instant invention, the pinholes are covered or filled with the same metal that constitutes the immersion coating itself. For example, pinholes or pores of immersion silver plate, are preferably capped with silver metal. In the context of this invention, the terms pinholes, microvoids, and pores, are synonymous and can be used interchangeably. They both denote incomplete coverage of the copper surface. Also, in this invention the term silver coating, deposit, plate, film, or layer, etc., can be used interchangeably.

The same applies to terms such as immersion, galvanic, displacement deposit, etc. They all denote metal deposition driven by electrons supplied by dissolving metal, as opposed to electrons delivered by chemical reducers. They too, will be used in this disclosure interchangeably.

Also, in this patent, the term electroless deposition signifies plating a metal via chemical reducing agents, as opposed to galvanic/displacement.

Further, the terms fill, plug, cover, cap, top , etc. are at times used interchangeably. They signify elimination of exposed dissimilar metals, i.e. copper and silver, to the atmosphere.

Finally, instant invention addresses pinholing in all metals that can be deposited by displacement mechanisms, even though the disclosure principally features immersion silver.

Again and at the risk of being redundant, it is the central object of this invention to cover pinholes with metal other than copper, and thereby repair, heal, cover, pinholes/pores, voids and other discontinuities that are intrinsic deficiencies of immersion metal deposits over copper in general, and silver deposits in particular.

Also, while the patent excludes covering pinholes with copper, it does nevertheless contemplate use of copper alloys to cap said pinholes and microvoids, for example alloys of copper with nickel, silver, cobalt, and alike.

In order to determine the optimal thickness of electrolessly deposited metal on top of immersion silver for the purpose of filling microvoids/pinholes in the immersion silver deposit and prevent creep corrosion, one will need to run routine experiments with varying plating times, temperatures and compositions of the electroless deposition process. This is especially true for electrolessly plated metals prone to passivation such as, for example electroless nickel. Ideally, one needs to determine the very minimal thickness of the electrolessly deposited metal necessary and sufficient to plug the microvoids in the silver immersion film that will prevent atmospheric corrosion, and yet will still secure the solderability advantage of the silver film. In a way, one needs to strike a balance between bare minimum thickness needed to repair pinholes, and excessive thickness that will risk passivation and poor solderability.

It is a further object of this invention to electrolessly deposit silver via chemical reducer, over and on top of the silver immersion layer, thereby repairing microvoids in the immersion silver film that expose the copper substrate to the environment.

A further preferred embodiment of this invention envisions additional deposition of silver and/or other metals except copper, over the pinholed/porous immersion silver via electroless plating, using electroless metal plating compositions that comprise reducing agents selected from the group comprising, hypophosphites, borohydrides, DMAB, formaldehyde, and the like.

Indeed, electroless metal depositions, as opposed to galvanic type displacement, are not self-limiting, as they do not require exposed copper for the deposition of silver to take place.

Such reducer-based electroless methods and compositions to be applied over immersion silver, must be carefully selected so as not to damage the silver immersion coating already covering the copper substrate and, more importantly, avoid undesirable deposition on the solder mask.

The mechanism that visualizes the embodiment of this invention to plate metal, preferably silver on top of immersion silver, makes use of the already existing immersion silver layer as a foundation to build upon, and help to initiate/trigger electroless plating. The immersion silver film thus acts as a precursor or starter for enabling reducer-based electroless metal deposition in general, or electroless silver in particular.

The patent avoids reducer-based silver deposition on the solder mask, which is unacceptable. Indeed, the hydrophobic solder mask surface will not be wetted by the aqueous electroless silver composition and will not receive extraneous silver plate. To further avoid extraneous silver metallization of solder mask, this patent also envisions a two-step process, namely immersing the copper-patterned PWB in the aqueous reducing agent, followed optionally by water rinse, and then immersing it in an aqueous silver solution.

Conversely, and perhaps preferably, the copper-patterned PWB can be immersed first in a silver-bearing solution, optionally water rinsed, and then exposed to a reducing solution capable of reducing the silver ions on the surface of the copper, to metallic silver. Again, the mechanism is one based on the hydrophobic behavior of the solder mask surface, vs. the hydrophilic nature of the clean copper surface. This two-step electroless plating embodiment thus capitalizes on the silver ion-bearing film entrained from the silver ion-bearing electrolyte, to form an electrolessly deposited silver layer, when it contacts the reducing solution. Above two-step embodiment of electroless silver deposition, in a way conveniently sidesteps the seemingly difficult-to-resolve stability and poor process control of electroless silvers of the prior art, wherein both the silver ions and reducer are in the same solution.

The reducer of choice for the two-step electroless silver deposition, will preferably be one that is active in mildly acidic, or mildly alkaline environment, depending on whether the ionic silver composition is acidic or alkaline.

The assumed mechanism of the two-step approach that strives to replace or repair the pinhole-plagued immersion deposition of silver, essentially hinges on chemically reducing a liquid, ionic silver-bearing film on the copper-patterned PWB emerging from a silver ion bearing composition, by exposing it to a reducer solution. It follows that one skilled in the art will formulate, by trial and error, an ionic silver electrolyte that leaves an appreciable silver concentration in the liquid film that is entrained from said formulation, before it will enter the liquid reducer bath.

It is hereby postulated, that in order to maximize the effectiveness of the two-step approach for achieving electroless deposition, one needs to ensure as high a concentration as possible of silver ions in the layer emerging from the ionic silver bath, and prior to its exposure to the reducing solution. In addition to formulating a bath with high concentration of ionic silver, this patent also envisions allowing the liquid layer to dry on the substrate, prior to its exposure to the reduction step.

This patent further envisions the use of silver ion bearing colloids, or ionic silver-bearing pastes, as preferred embodiments of the first step in the two-step electroless silver plating process, and prior to the second, or reducer step. Indeed, the PWB technology abounds with processes that use silk screening as a way to apply fluid coatings to copper substrates.

Also, the two-step process can be repeated several times to accommodate a desired plate thickness. Furthermore, the two-step process lends itself to automation, for example via horizontal spray machines. If one opts for an electroless silver composition to plate additional silver over the immersion silver film, the electroless composition will preferably use reducers that will function at a pH similar to the one that prevails in the displacement silver solution. This again, in order not to damage the immersion silver that has already been deposited over the copper pattern.

It is thus desirable to choose a reducing agent that functions at moderately low pH, for example hypophosphites, borohydrides, DMAB, and the like, especially in an embodiment of this invention that contemplates nickel or cobalt to cover pinholes in the silver layer.

A still further embodiment of the invention prefers to use reducers that will operate at temperatures close to ambient. This, to minimize attack of the immersion silver coating, if said silver immersion film is to be capped with electroless metal such as for example electroless nickel, cobalt, etc.

When choosing electroless gold or palladium to cover pinholes, formulations can be adapted from the prior art directed to plate electroless gold or palladium over electroless nickel, a process practiced to preserve solderability and corrosion protection of PWB's. A still further preferred embodiment of this invention uses emulsions, microemulsions, or pastes of metallic silver-bearing compositions that will fill the capillaries or pores present in the silver coating. Such compositions can be formulated on the basis of the widely practiced conductive silver pastes.

The invention further envisions the embodiment that will cover microvoids via vacuum deposition, metal sputtering, and the like. The challenge in this latter approach, is to avoid extraneous, undesirable deposition on the solder mask. Furthermore, one is confined to processes that operate at temperatures that will not damage the PWB laminate, typically glass epoxy.

Again, in an embodiment directed to use silver emulsions for repairing pinholes, one will formulate, microemulsions that emulate conductive silver paste formulations. They should be designed to maximize affinity of silver atoms to exposed silver pinholes reaching the copper substrate.

Finally, while this patent focuses principally on elimination of pinholes and microvoids by capping them with metal other than copper, it optionally comprises use of organic finishes to additionally protect the metal-capped pinholes and microvoids against corrosive environments.

### EXAMPLES

1. A through hole copper plated PWB panel was cleaned, microetched, water-rinsed, then immersed in a dilute acidic palladium chloride solution at R.T. for about one minute, water-rinsed, followed by immersion for 5 min. at 50° C. in an electroless silver composition comprising 10 g/l sodium thiosulfate, 10 g/l sodium sulfite, 0.2 g/l silver nitrate, and 5 g/l ethylene diamine tetraaceticacid (EDTA) with the pH adjusted to 7.5 with sodium carbonate. After the panel was rinsed and hot-air dried, it displayed a uniform silver film.

2. A PWB copper plated panel similar to the one used in Example 1 and pretreated as in Example 1, was dipped in a dilute acidic palladium chloride solution, rinsed, then plated for 30 min. in a hypophosphite-bearing electroless nickel solution at 50° C., adjusted with ammonia to a ph 8-9.

Electroless nickel thickness was determined at about 3 microns. The panel was rinsed, dipped for about 1 min. in dilute acidic palladium chloride, then plated in the electroless silver solution similar to the one used in Example 1, for 10 min. at 50° C.

Following rinsing and drying, the panel displayed a uniform silver coating over the electroless nickel plate.

3. A PWB copper plated panel, similar to the one used in Example 1, was plated with about 0.25 micron immersion silver film, using a commercial, displacement type silver composition and process as instructed by the vendor.

The panel was rinsed, dipped for about 1 min. in dilute acidic palladium chloride solution, rinsed, followed by immersion for 10 min. in the electroless silver solution at 50° C., similar to the one used in Example 1.

The dried panel was observed under a microscope, with no indication of pinholes or microvoids reaching down to the copper substrate.

4. A PWB copper plated panel, similar to the one used in Example 1, was plated with about 0.25 micron immersion silver, following vendor's process composition and instructions.

The panel was rinsed, dipped for about 1 min. in dilute acidic palladium chloride solution, then plated for about 10 min. in an alkaline electroless nickel bath at 50° C., similar to the one used in Example 2.

Under microscopic examination, there was no indication of pinholes or microvoids reaching down to the copper substrate.

1. The method of repairing pinholes in immersion-plated metal coatings covering metallic substrates, said method comprising capping said pinholes with metal.

2. The method of claim 1, wherein the metallic substrate comprises copper.

3. The method of claim 1, wherein the immersion-plated metal coating comprises silver.

4. The method of claim 1, wherein the immersion -plated metal coating comprises silver and is capped by electrolessly deposited metal.

5. The method of claim 1, wherein the immersion-plated metal coating comprises silver and is capped with electrolessly deposited silver metal.

6. The method of claim 4, wherein the electrolessly deposited metal is selected from the group consisting of silver, nickel, cobalt, gold, palladium, alloys thereof, and their alloys with copper.

7. The method of claim 6, wherein the metallic substrate comprises a throughole plated PWB.

8. The method of depositing silver metal on a throughole copper patterned PWB, comprising contacting said PWB with a composition comprising ionic silver, then contacting it with an aqueous solution of a reducing agent capable of reducing silver ions to metallic silver.

9. The method of claim 8, wherein the ionic silver comprises in a colloidal suspension.

10. The method of claim 9, wherein the ionic silver is comprised in a paste.

11. The method of claim 8, wherein the ionic silver is comprised in an aqueous solution.

12. The method of achieving a pinhole-free immersion silver film, comprising immersing a copper-patterned PWB covered with an immersion silver deposit in an aqueous ionic silver solution, then contacting the PWB with a reducing solution capable of reducing silver ions to metallic silver.

13. The method of claim 12, wherein the reducing solution comprises an aqueous alkaline formaldehyde solution.

14. The method of repairing pinholes in immersion deposited metal films, said method comprising capping said pinholes with vapor deposited metal.
